(19) United States
(12) Patent Application Publication
(10) Pub. No.: US 2024/0428852 A1
(43) Pub. Date: Dec. 26, 2024

(54) MEMORY ARRAY INCLUDING REPEATER BUFFER

(71) Applicant: BRILLNICS SINGAPORE PTE. LTD., Singapore (SG)

(72) Inventor: Kwuang-Han CHANG, Singapore (SG)

(21) Appl. No.: 18/708,172

(22) PCT Filed: Nov. 18, 2022
(86) PCT No.: PCT/SG2022/050843

§ 371 Date: May 7, 2024

Related U.S. Application Data
(60) Provisional application No. 63/281,552, filed on Nov. 19, 2021.

(51) Int. Cl. G11C 11/419

(52) U.S. Cl. CPC G11C 11/419

(57) ABSTRACT

The present application relates to repeaters for memory arrays. In some embodiments, a plurality of repeaters may be coupled to a respective one of a plurality of memory cells. Each repeater may include: a first input node coupled to a first bit line and a second input node coupled to a second bit line; a first output node coupled to the first bit line and a second output node coupled to the second bit line; a pair of switches configured to couple to the first bit line and the second bit line responsive to receiving an input signal; and a set of cross-coupled invertors coupled to the pair of switches, wherein the pair of switches and the set of cross-coupled invertors form a shunt connection between the first bit line and the second bit line responsive to the input signal being received by the pair of switches.

### BACKGROUND

Memory arrays include a number of memory cells, each configured to store data. To write data to the memory cells, a signal (e.g., a write signal) is sent to certain memory cells along bit lines. The greater the number of memory cells, the longer the bit line will be. Typically, the bit lines are fabricated from a wire having a non-zero impedance and, as a result, the signal can degrade as the memory cells are further from each bit line's respective bit line driver. Thus, the signal provided to the n-th memory cell may not cause the data to be appropriately written to that memory cell. One solution to the aforementioned problem is to insert repeaters within each column of the memory array. The repeater functions to regenerate, reform, and output a received signal. In this way, the signal is intended to remain consistent across the bit line's length.

Use of repeaters, however, can introduce additional problems. For instance, repeaters are typically inserted by breaking the bit line and connecting one of the broken ends to the repeater's input and the other broken end to the repeater's output. This increases the cost of fabricating memory cells, and can also cause issues with minimizing the size of the memory array. For example, the costs for fabricating the memory cells may be higher since the on-chip area needed for conventional repeaters is higher than the on-chip area needed for SRAM repeaters. Additionally, the repeaters are not needed for memory reads, and so in order to read data from the memory cells, the repeaters need to be bypassed, disabled, or reversed. These and other drawbacks exist.

### SUMMARY

The following is a non-exhaustive listing of some aspects of the present techniques. These and other aspects are described in the following disclosure.

Some aspects include a repeater for a memory array. The repeater may include: a first input node coupled to a first bit line and a second input node coupled to a second bit line; a first output node coupled to the first bit line and a second output node coupled to the second bit line; a pair of switches configured to couple to the first bit line and the second bit line responsive to receiving an input signal; and a set of cross-coupled invertors coupled to the pair of switches, wherein the pair of switches and the set of cross-coupled invertors form a shunt connection between the first bit line and the second bit line responsive to the input signal being received by the pair of switches.

Some aspects include a memory array including a plurality of repeaters, such as the repeater described above.

Some aspects include an imaging device including a plurality of repeaters, such as the repeater described above.

Some aspects include a system including a plurality of repeaters, such as the repeater described above.

### BRIEF DESCRIPTION OF THE DRAWINGS

The above-mentioned aspects and other aspects of the present techniques will be better understood when the present application is read in view of the following figures in which like numbers indicate similar or identical elements:

FIGS. 1A-1C are example memory array representations, in accordance with various embodiments;

FIGS. 2A-2B are example memory array represents and schematics, in accordance with various embodiments;

FIG. 3 is an example memory array including repeaters, in accordance with various embodiments;

FIG. 4 is an example memory column of the memory array of FIG. 3 including a schematic representation of the repeater, in accordance with various embodiments;

FIGS. 5A-5C are example signal diagrams of a differential signal absent skew at various nodes of the memory column of FIG. 4, in accordance with various embodiments;

FIGS. 6A-6C are example signal diagrams of a differential signal having skew at various nodes of the memory column of FIG. 4, in accordance with various embodiments;

FIGS. 7A and 7B are an example memory column for a memory array including duty-cycle correction (DCC) repeaters and a zoomed-in schematic of an example DCC repeater, respectively, in accordance with various embodiments;

FIGS. 8A-8C are example signal diagrams of a differential signal absent skew at various nodes of the memory column of FIG. 7A, in accordance with various embodiments;

FIGS. 9A-9C are example signal diagrams of a differential signal having skew at various nodes of the memory column of FIG. 7A, in accordance with various embodiments;

FIGS. 10A and 10B are an example memory column for a memory array including SRAM repeaters and zoom-in schematic of an example SRAM repeater, respectively, in accordance with various embodiments; and

FIG. 11 is an example block diagram showing an example configuration of a solid-state imaging device, in accordance with various embodiments.

While the present techniques are susceptible to various modifications and alternative forms, specific embodiments thereof are shown by way of example in the drawings and will herein be described in detail. The drawings may not be to scale. It should be understood, however, that the drawings and detailed description thereto are not intended to limit the present techniques to the particular form disclosed, but to the contrary, the intention is to cover all modifications, equivalents, and alternatives falling within the spirit and scope of the present techniques as defined by the appended claims.

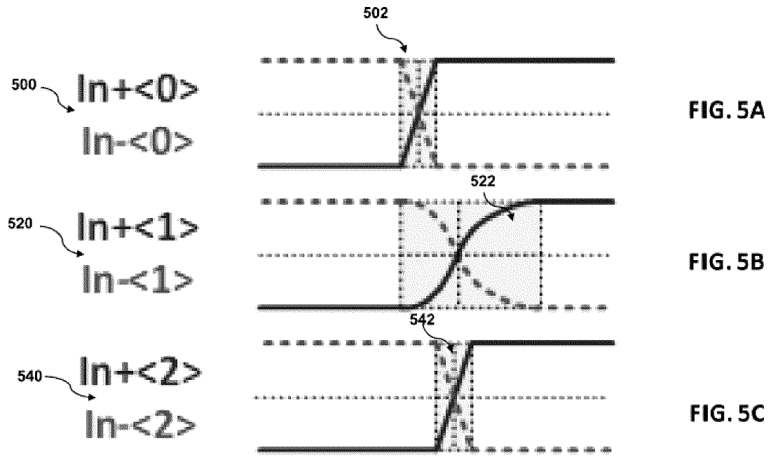

In the drawings, “In±<0>” indicates the source nodes of BL driver, “In±<1>” indicates the input nodes of first repeater driven by BL driver along with the wires from BL driver to the first repeater, “In±<2>” indicates the output nodes of first repeater to drive the second repeater along with the wires from the first repeater to the second repeater, and “In±<α>” indicates the intermediate nodes within the wires from BL driver to the first repeater, which are the balanced points that the strength of BL driver is equivalent to the strength of first repeater. In FIGS. 5A-5C, 6A-6C, 8A-8C and 9A-9C, the solid lines represent signals at “In+<0>”, “In+<1>”, “In+<2>” and “In+<α>” respectively, and the thick dashed lines represent signals at “In−<0>”, “In−<1>”, “In−<2>” and “In−<α>” respectively.

### DETAILED DESCRIPTION OF CERTAIN EMBODIMENTS

To mitigate the problems described herein, the inventor had to both invent solutions and, in some cases just as importantly, recognize problems overlooked (or not yet foreseen) by others in the memory devices. Indeed, the inventor wishes to emphasize the difficulty of recognizing those problems that are nascent and will become much more apparent in the future should trends in industry continue as the inventors expect. Further, because multiple problems are addressed, it should be understood that some embodiments are problem-specific, and not all embodiments address every problem with traditional systems described herein or provide every benefit described herein. That said, improvements that solve various permutations of these problems are described below.

Conventional memory circuits can be organized into rows and columns, both in physical layout and in electrical operation. As the number of memory cells becomes larger, the physical size of the memory array also becomes larger. When selecting a given row of memory cells, a large number of memory cells can be activated. This activation is typically performed by a row decoder on a row line, also referred to herein interchangeable as a “word” line. The activation of the row connects the memory cells in that row with their respective bit lines, communicatively coupling the memory cells in the row with sense amplifiers (SAs) to sense the readout signals from the activated memory cells. As more and more memory cells are included in a given row, the power needed to activate that row also increase. For example, activation of one row of a 1024×1024 memory array will result in 1024 memory cells being activated, which requires a lot of power.

To reduce the amount of power that is needed to activate memory cells in a memory array, a repeater may be used. In addition, repeaters also can be used to ensure that data is capable of being written to SRAM memory cells correctly without interference and/or noise deterioration. A repeater is configured to maintain application of an activation level for a predefined amount of time. In some embodiments, each repeater receives a row line (RL) via an n-channel pass gate, whose gate is connected to a select (SEL) line. The pass gate may be connected to the input of an inverter, the output of which is connected, via a buffer inverter, to the output row line. A latch may be formed via 2 inverters (e.g., which may be CMOS inverters). Repeaters may also include an n-channel transistor, having its source-to-drain path connected between the input of one of the inverters of the latch and ground, and the gate is controlled by a reset line.

Conventional image sensors (e.g., such as a CMOS image sensor) captures and processes scene information via a rolling scan (RS) operation. With RS operations, the scene information is captured and processed line by line. However, when the scene includes objects that move, or when flash is used, the RS operation can cause image artifacts to be created. A “global shutter” operation overcomes the challenges of RS operations. In global shutter operations, the image sensors are configured to capture, globally, all of the pixels in the image sensors (e.g., the image sensors can capture and process scene information via a parallel pixel operation). One task of pixel parallel operation is to acquire and convert all sensor signals in parallel. Digital pixel sensor application in CMOS image sensors (CIS) enables integration of the sensor and signal chain in an “in-pixel” area, and can be implemented using a conventional 2D IC or a 3D stacked IC. The signal chain includes Analog-to-Digital Conversion (ADC) and memory to be read out.

Pixel parallel operation can be split into three parts. First, a signal, generated by a pixel sensor in an analog domain, is acquired. Second, analog-to-digital conversion of the signal is performed. Third, the converted signal in digital domain is readout. The output signal may be readout using peripheral readout circuits. However, throughput of the readout signal is limited by the peripheral readout circuits. Therefore, even though the first and second steps can be performed with pixel parallel operation, the readout may still need to be performed row by row or column by column. The memory readout can be a bottleneck to the image sensor's performance as the memory readout is done row by row or column by column as there is only one readout circuit.

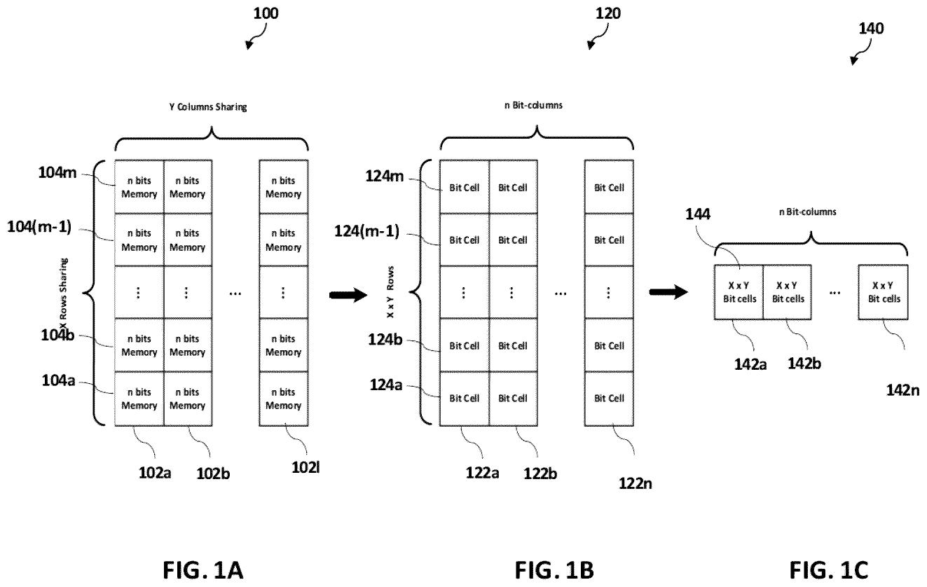

The most efficient use of available pixel area necessitates the use of multi-pixel grouping. This allows the shared array to be fully utilized while also satisfying the physical layout constraints. For memory write, the BL drivers can write all of the memory cells in a column at once. The max number of bits that the BL driver can write at once is the number of bit cells in the column, where the minimum number of bit cells is 0 bit cells. Therefore, the number of cells in a given column can span a wide range of bit cells (e.g., 4 or more, 16 or more, 64 or more, 512 or more, 1024 or more, etc.). As an example, with reference to FIG. 1A, memory array 100 may include columns 102a-1021 of bit cells, where each column includes m bit cells (e.g., memory array 100 may include rows 104a-104m of bit cells. Each bit cell may be an n-bit memory cell. Thus, the total number of memory cells in memory array 100 may be Ix m (e.g., X×Y) n-bit memory cells. To make the most efficient use of the physical layout, memory array 100, which includes/rows and m columns of n-bit memory cells (e.g., (X rows×Y columns)×n-bits of memory), may be allocated into a different grouping of pixels, as seen in memory array 120 of FIG. 1B. As seen in FIG. 1B, memory array 120 may include rows 124a-124m and bit-columns 122a-122 n. Thus, in memory array 120, the number of rows is X×Y and the number of memory columns (e.g., bit-columns) is n, where each bit-column include X×Y bit cells. Memory array 120 may be further reduced to memory array 140 of FIG. 1C, which may include n memory columns 142a-1421 of X x Y bit cells 144. Thus, the X rows×Y columns×n bits of memory of memory array 100 may be allocated as (X×Y) rows×n bit-columns)×(1 bit cell), where each bit-column is a width of one bit cell in physical layout.

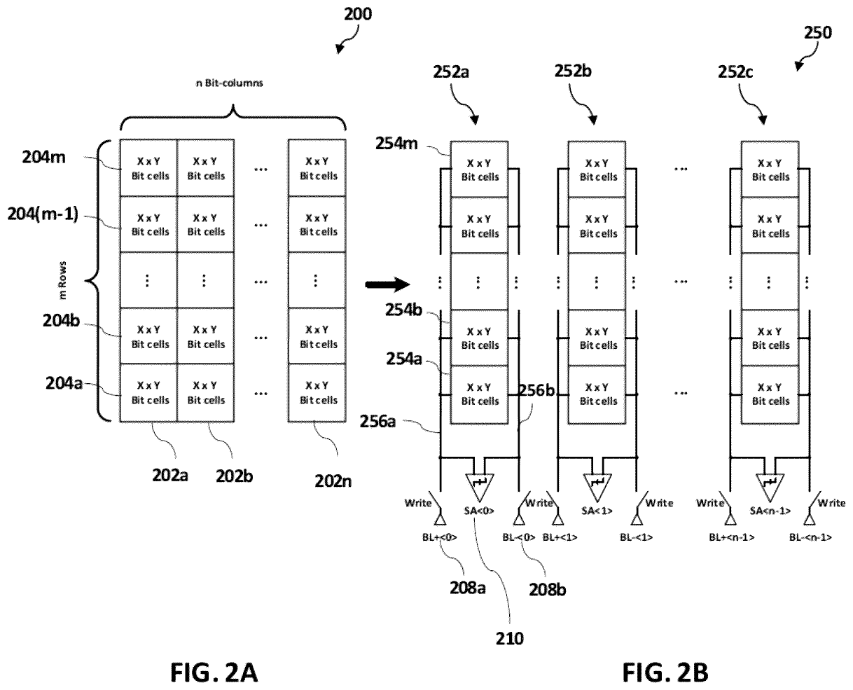

As seen from FIGS. 2A-2B, peripheral circuits are needed to read and write data to the memory cells of a memory array. For example, memory array 200 includes m rows 204a-204m and n bit-columns 202a-202 n. Each memory cell includes X×Y bit cells, as detailed above with respect to FIGS. 1A-1C. In order to drive and sense rows 204a-204m of pixels, peripherical circuits may be needed. In some cases, bit-wise peripheral circuits may be used to write/read the m rows 204a-204m of X×Y bit cells. In the example of FIGS. 2A-2B, m equals a total row number divided by X. As seen in FIG. 2B, memory array 250 may include sense amplifiers (SAs) 210. Each bit-column (e.g., bit-columns 252a-252c) may include an instance of sense amplifier 210, which may be used for performing memory read operations, where data stored by each bit cell of a given bit-column may be readout. Sense amplifiers may be limited by loading of bit-lines (BLs) 256a and 252b, as there can be a large amount of RC loading along with the m rows×(X×Y) bit cells (e.g., rows 254a-254m). However, this typically is not the bottleneck for sensor operation time. Each bit-column of memory array 250 may also include bit-line (BL) drivers 208a and 208b. BL drivers 208a and 208b may be used for memory write operations. Each of BL drivers 208a and 208b may write to all of the memory cells in a given bit-column at once, and thus may drive a large variation of bit cells in terms of ADC results (e.g., a maximum driving signal being for driving m rows by (X×Y) bit cells, and a minimum driving signal being for driving no bit cells). Furthermore, BL drivers 208a, 208b may not only drive the different numbers of SRAM cells, but BL drivers 208a, 208b may also drive the BL wire loading.

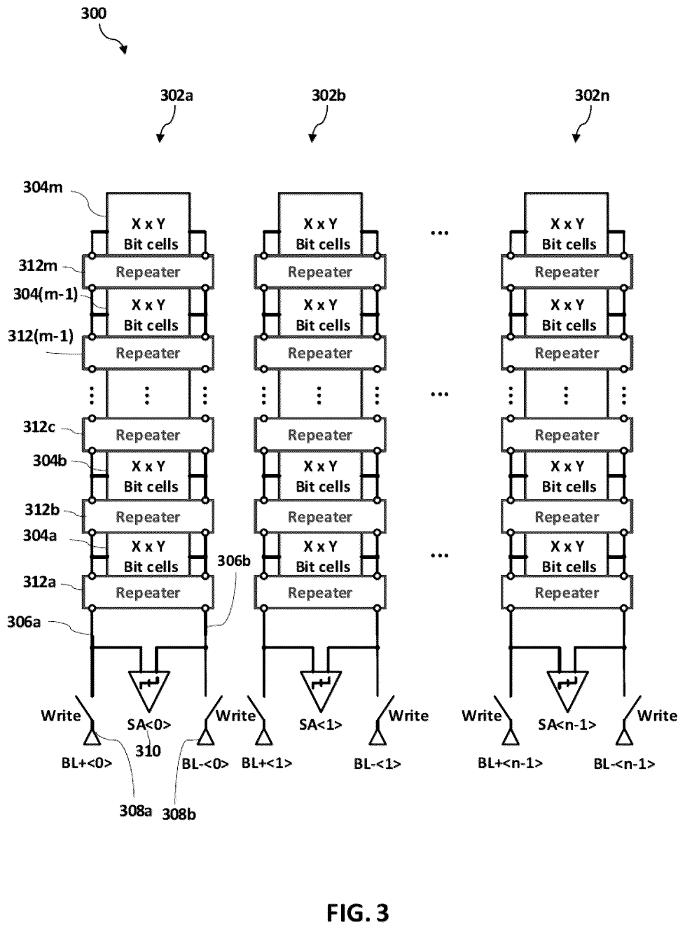

In some embodiments, to prevent signal loss, signal change, or other changes to the driving signal that can occur over a length of each bit line, one or more repeaters may be inserted into the memory array. As an example, with reference to FIG. 3, memory array 300 may include bit-columns 302a-302 n and memory cells 304a-304m. Each memory cell may include X×Y bit cells. Each of bit-columns 302a-302 n may include m repeaters 312a-312m. In some cases, a given bit-column may include other amounts of repeaters (e.g., less than m repeaters, greater than m repeaters). Furthermore, memory array 300 may include bit line (BL) drivers 308a and 308b, which may output a driving signal to memory cells 304a-304m along bit lines (BLs) 306a and 306b. In particular, BLs 306a and 306b may couple to an input node at a first repeater, 312a, and an output node of first repeater 312a may couple to a first memory cell 304a and an input node of a second repeater 312b. The grouping of repeater-memory cell may repeat along each bit-column.

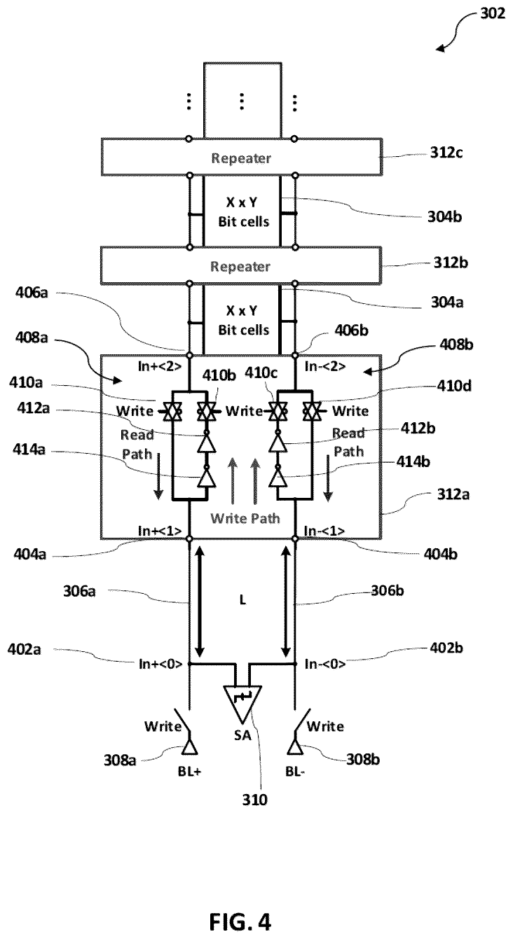

As seen from FIG. 4, each repeater (e.g., repeaters 312a-312m) may include a first circuit 408a and a second circuit 408b for each of BLs 306a, 306b. First circuit 408a may include inverters 412a, 414a and transmission gates 410a, 410b, and second circuit 408b may include inverters 412b, 414b and transmission gates 410c, 410d. For example, as seen with reference to FIG. 4, an example circuit diagram of first repeater 312a is depicted. Input nodes 404a, 404b of first repeater 312a may connect to a first node 402a and 402b along BLs 306a, 306b, respectively. In some cases, each of bit lines BLs 306a, 306b between first node 402a, 402b and input nodes 404a, 404b may have a length L. Bit lines 306a, 306b may then be used to connect repeater 312a to memory cell 304a at second node 406a, 406b. Inverters 412a, 412b, 414a, 414b may be used to reshape the driving signal output by BL drivers 308a, 308b. Transmission gates 410a-410d may operate as switches to “enable” or “bypass” repeater 312a″ (e.g., from a “read” mode to a “write” mode).

In some embodiments, repeaters may be used due to signal delay time, which is an amount of time it takes for a signal to travel from one end of a wire to another. In particular, the time delay increases proportionally to the distance. Thus, it can take less time to use two separate wires of length L/2 then to use a signal wire of length L. A circuit—a repeater—may be put in between two wires to move the signal from one wire to another. The process of reducing the delay of a wire by cutting segmenting it (e.g., cutting in half) and inserting a repeater is known as “repeater insertion.”

In some embodiments, repeaters 312a-312m require a break in a signal path of each of BLs 306a, 306b. At the break, each repeater may be inserted and then BLs 306a, 306b may be reconnected to the repeater. In some embodiments, the repeaters may be implemented for memory write operations and may not be needed for memory read operations. Thus, while insertion of repeaters 312a-312m in each bit-column of the memory array can allow for even distribution of load variation of bit cells into small segments and can divide the BL loading into numerous small segments, it may also necessitate additional array for the memory array, requires a break to be created in the signal path of each bit line, and may need to be bypassed, disabled, or reversed during read operations.

There are some side effects to the repeater insertion described above. For example, with reference to FIGS. 5A-5B, which respectively represent a graph 500 of a differential signal at nodes 402a, 402b (e.g., at an output of BL drivers 308a, 308b) and a graph 520 of the differential signal at nodes 404a, 404b (e.g., an input of repeater 312a). The buffer repeater configuration described with respect to the memory arrays of FIGS. 3 and 4 may cause the differential driving signal output by BL drivers 308a, 308b to gradually and/or smoothly get slower. This can lead to increased DNL and increased noise in the converted signal of n-bit memory in digital domain. The DNL is an error measurement representing a difference between an actual step width and an ideal value of 1 LSB. For an ideal ADC, in which the differential nonlinearity coincides with DNL=0 LSB, each analog step equals 1 LSB, where:

$$1 LSB = {V}_{FSR} / {2}^{N} . \qquad Equation 1$$

In Equation 1, V_{FSR} is the full-scale range and N is the resolution of the ADC. In some cases, the transition values may be spaced exactly 1 LSB apart. For example, if DNL=−1, this may indicate that code is missing. The DNL may be expressed using Equation 2: It is defined as follows:

$$DNL = {\vert}^{{V}_{D + 1} - {V}_{D}} {/}_{{V}_{Ideal LSB}} - 1 \vert . \qquad Equation 2$$

In Equation 2, D is between 0<D<2^{N}−2, where VD represents a physical value of a digital output code D, N represents the ADC's resolution, and V_{Ideal} LSB represents an ideal spacing for two adjacent digital codes.

Further, as seen by FIGS. 5B and 5C, the differential signal may abruptly be reshaped and may include a larger discontinuity, which can increase fixed-pattern noise (FPN) where the row FPN may be greater and more severe than the FPN due to the discontinuity. For example, the reshaping of the differential signal from nodes 404a, 404b to nodes 406a, 406b can cause the crossing point to shift in time. Thus, a width of the meta-stable zone of the differential signal can increase significantly between nodes 402a, 402b and nodes 404a, 404b (e.g., a width of metastable zone 502 of graph 500 increases with respect metastable zone 522 of graph 520). Thus, while the repeaters may reshape the differential signal at the output of the repeater (e.g., as seen by graph 540 of FIG. 5C representing the differential signal at nodes 406a, 406b), metastable zone 542 may shift as compared to metastable zone 502 representing the differential signal at nodes 402a, 402b. As the metastable zone increases and shifts, signal levels change, and the logical level of the differential signal may change. This can lead to faulty behavior by the memory array as first circuit 408a and second circuit 408b may be unable to settle to a stable 0 or 1-logical state. This can cause signal loss and system failure of the image sensor.

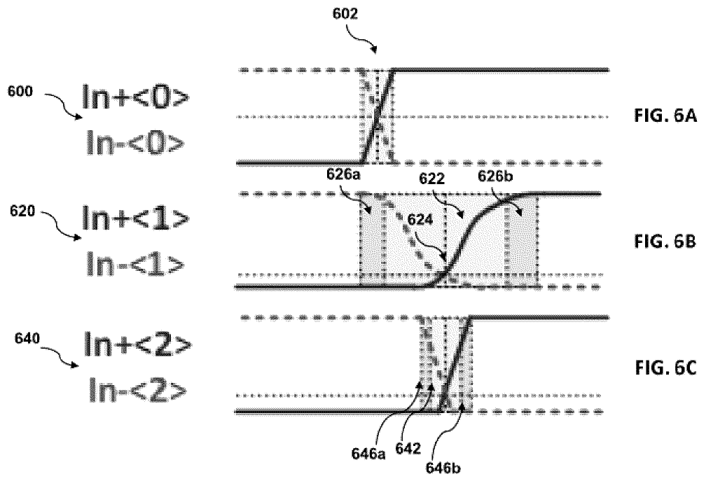

FIGS. 5A-5C represent examples of the some of the side effects of repeater insertion in the scenario where no skew is present. In practice, however, skew is present due to natural imperfections in the construction of BLs 306a, 306b (e.g., such as non-uniformity in the material forming wires used as bit lines). Skew may also be present due to the imperfections in the construction of the BL drivers (e.g., BL drivers 308a, 308b) and the repeaters (e.g., repeaters 312a-312m). FIGS. 6A-6C are example signal diagrams of a differential signal having skew at various nodes of the memory column of FIG. 4, in accordance with various embodiments. In the skewed case, there is unbalanced loading and/or driving in BLs 306a, 306b, which can result in a skewed zero-crossing point. For example, as seen in graph 600 of FIG. 6A, metastable zone 602 at nodes 402a, 402b may be substantially similar to that of the non-skewed case depicted by graph 500 of FIG. 5A. However, as seen from graph 620 of FIG. 6B, metastable zone 622 has increased in width as compared to metastable zone 602. In particular, the metastable zone 622 may include skew-inducted metastable zones 626a, 626b, which increases a width of metastable zone 622 as compared to a width of metastable zone 522 representing the differential signal at nodes 404a, 404b for the non-skewed case. Furthermore, a zero-crossing point 624 of the differential signal may be skewed as well, as seen by FIG. 6B (e.g., zero-crossing point 624 is lowered as compared to FIG. 5B). After reshaping/regenerating, the differential signal at nodes 406a, 406b, as seen by graph 640 of FIG. 6C may retain the skewed zero-crossing point and increased width of metastable zone 642, as seen by skew-inducted metastable zones 646a, 646b This can result in DNL and noise increasing more than in the non-skewed case. Furthermore, skew-induced metastable zone 646a, 646b may be reshaped and continue propagating along bit lines 306a, 306b. As the signal propagates, skew-induced metastable zone 646a, 646b will keep expanding, which causes the DNL, noise, FPN, and row FPN to continue to increase, where row FPN is a subset of FPN.

In some embodiments, the technical problems discussed above with respect to memory arrays 300 including repeaters inserted such as depicted in FIG. 4 can be overcome using the memory columns described below. “Memory columns” may also be referred to herein as “bit columns.” In particular, some embodiments describe a technical solution to the technical problem described above, where the technical solution includes (i) a duty-cycle corrector (DCC) repeater and (ii) an SRAM repeater, which can each produce a technical effect of overcoming the technical problem described above. The DCC and SRAM repeaters described below overcome technical problems including, but not limited to, (which is not to suggest that other lists are limiting), requiring a break in the data path for inserting the repeaters in series with the memory cells, causing large propagation delays due to the cascaded stack of repeaters, causing the differential signal's skew to propagate and accumulate, cause an abrupt discontinuity in the vicinity of each repeater (e.g., along BLs 306a, 306b proximate to nodes 404a, 404b and nodes 406a, 406b), and requiring a separate path for reading and writing. Furthermore, a technical advantage of both the DCC repeater and the SRAM repeater, as detailed below, is that both the DCC repeater and the SRAM repeater described below employ fewer transistors than the repeater depicted in FIG. 4, making fabrication more economical. For example, the repeaters of FIG. 4 (e.g., repeaters 312a-312m) may include 16 transistors, whereas the DCC repeater and the SRAM repeater described below may include 8 transistors and 6 transistors, respectively. Still further, the effective driving load for both the DCC repeater and the SRAM repeater described below may be less than that needed for the repeaters of FIG. 4. Additionally, the SRAM repeater described below may include fewer control signals, can be merged into an optimized memory array having a most compact layout possible (e.g., due to the lack of additional peripheral circuitry and lack of a need for signal path breaks), and can have a high memory yield with identical surrounding SRAM-like repeater layouts.

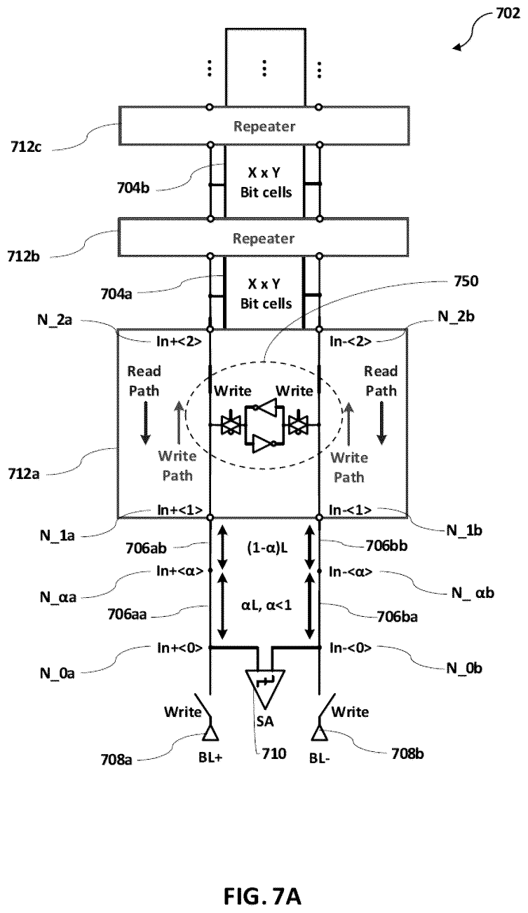

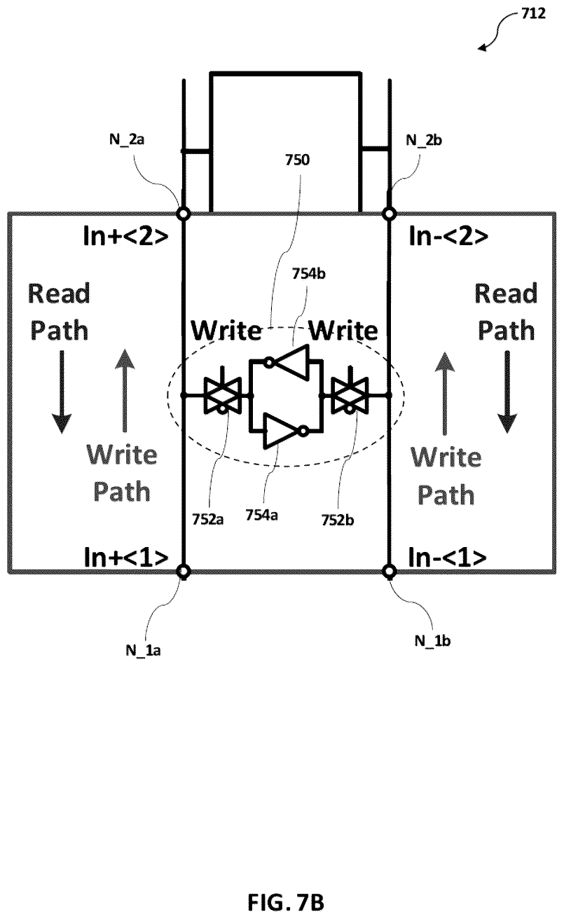

FIGS. 7A and 7B are an example memory column for a memory array including duty-cycle correction (DCC) repeaters and a zoomed-in schematic of an example DCC repeater, respectively, in accordance with various embodiments. FIG. 7A shows an example memory column 702 of a memory array. In particular, a memory array may include n columns that are the same or similar to memory column 702.

In some embodiments, memory column 702 may include m memory cells, such as memory cells 704a and 704b, which may be connected in series to bit lines driven by bit line (BL) drivers 708a, 708b, respectively. Each memory cell of memory column 702 may be include X×Y bit cells. Furthermore, each memory column may include a sense amplifier (SA) 710, which may be used for reading data from the memory cells.

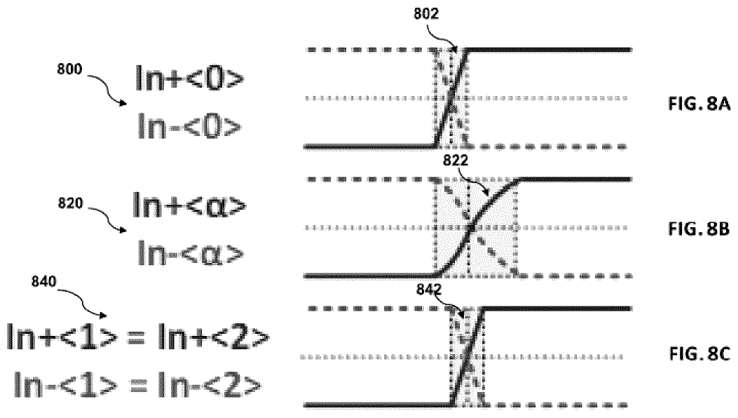

In some embodiments, initial nodes N_0a and N_0b may be coupled to BL drivers 708a, 708b, respectively. As seen by graph 800 of FIG. 8A, in the non-skewed case, at initial nodes N_0a, N_0b may have a metastable zone 802. The width of metastable zone 802 may be substantially similar to that of metastable zone 502 of FIG. 5A, and the previous description may apply.

In some embodiments, an intermediate node, such as intermediate nodes N_αa, N_αb, may be inserted along the each bit line. In particular, intermediate nodes N_αa, N_αb may segment a length (L) of bit line between initial nodes N_0a, N_0b and intermediate nodes N_αa, N_αb into first portions 706aa, 706ba having a length αL, where a is less than 1, and second portions 706ab, 706bb, having a length (1−α) L. Nodes N_αa and N_αb may be placed at a balance point between the RC decay of the differential signal and DCC regeneration. For example, a may equal L/2. In some embodiments, a may be determined via simulation using constraints from the memory array's desired design. As seen from graphs 800 and 820 of FIGS. 8A and 8B, respectively, the differential signal from initial nodes N_0a and N_0b to intermedia nodes N_αa and N_αb may gradually/smoothly get slower, having an improved effective length at αL (e.g., where αL is <L). From graphs 820 and 840 of FIGS. 8B and 8C, respectively, the differential signal may gradually/smoothly regenerate, which lowers the DNL and noise, and produces no row FPN. Additionally, the width of metastable zone 842 remains substantially similar to that of metastable zone 802, and there is minimal shifting of the zero-crossing point. In particular, the zero-crossing point should have no skew along the y-axis and a minimal shift in time delay (e.g., the x-axis). Furthermore, the differential signal across input nodes N_1a and N_1b is equivalent to that of output nodes N_2a and N_2b. Thus, the differential signal at the input of repeater 712a is the same (or substantially similar) to the differential signal at the output of repeater 712a. Similar properties may be achieved for the other repeaters (e.g., repeaters 712a-712c) of memory column 702.

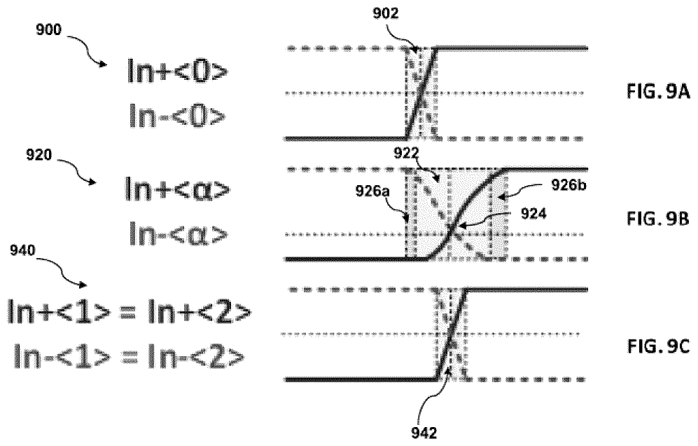

While FIGS. 8A-8C represented examples of a non-skewed case of the differential signals across various nodes of memory column 702, FIGS. 9A-9C represent examples of the skewed-case. In the skewed case, the loading/driving signal output by BL drivers 708a, 708b may be imbalanced. As seen from graph 900 of FIG. 9A, metastable zone 902 may be substantially similar to that of metastable zone 802, and the previous description may apply. In graph 920 of FIG. 9B, the metastable zone 922 may still expand relative to a width of metastable zone 902, however a size of skew-induced metastable zones 926a, 926b may be smaller than that of the repeater of FIG. 4. In graph 940 of FIG. 9C, the metastable zone 942 may again be reformed, however the shift of the differential signal may be reduced relative to the shift induced by the repeaters in FIG. 4. Furthermore, because the differential signal at input nodes N_1a, N_1b equals that at output nodes N_2a, N_2b, the propagates signal will have less delay and less degradation than in the repeaters of FIG. 4. In some embodiments, having the effective length αL of the bit line between initial nodes N_0a, N_0b and intermediate nodes N_αa and N_αb be less than length L (e.g., length of bit lines 306a, 306b of FIG. 3 between the initial nodes and the input nodes of the repeater), the width of the metastable zone, DNL, and noise may increase for the skewed case, as seen by graphs 900, 920, 940 of FIGS. 9A-9C, however the increase may be less than that of repeater 312a of FIG. 3. Further still, memory column 702 may cause the skew-induced metastable zones 926a, 926b may be reshaped, and the zero-crossing point 924, corrected. Additionally, the skew may be reset and cleared by the DCC repeater (e.g., repeater 712a). In some embodiments, the DCC repeater (e.g., repeater 712a) may pull out-of-phase differential signals back to be at 180-degrees separation. Additionally, the DCC repeater may also be able to pull the zero-crossing point back to mid-rail. For example, zero-crossing point 924 of graph 920, which may not be at midline, may be pulled back to mid-line in graph 940.

FIG. 7B is an zoomed-in circuit diagram of an example repeater 712 from memory column 702. In particular, repeater 712 may include input nodes N_1a, N_1b and output nodes N_2a, N_2b. DCC repeater circuit 750 may be inserted between the bit lines connecting input nodes N_1a, N_1b and output nodes N_2a, N_2b, respectively. For example DCC repeater circuit 750 may form a shunt connection to the bit lines. As a result, no signal path breaks may be included in memory column 702 using DCC repeater circuit 750.

DCC repeater circuit 750 may include a first switch 752a and a second switch 752b. Each of switches 752a, 752b may switch “on” or “off,” depending on the input signal. The input signal may refer to a BL driving signal, and a control signal may refer to a write signal. For example, when provided with an input signal (e.g., a signal output by BL drivers 708a, 708b), the input signal may be transmitted to inverters 754a, 754b. In some embodiments, switches 752a, 752b may be transmission gates formed using a PMOS transistor and an NMOS transistor connected in parallel. The drain and source terminals of the PMOS and NMOS transistors may be connected, while the gates are coupled to each other via an inverter. For instance, when the input signal is logical high (e.g., logical 1), the device may be in a write mode (e.g., NMOS on, PMOS on), whereas when the input signal is logical low (e.g., logical 0), the device may be in read mode (e.g., NMOS off, PMOS off). In some cases, the transmission gates may be “open (off)” when memory column 702 is in a “read” mode, where data stored in each memory cell 704 may be readout across the bit lines and sensed by SA 710. When the signal across the transmission gates (e.g., switches 752a, 752b) is logical 1, the transmission gates may be “closed (on),” and the transistors of the transmission gates may conduct the input signal (e.g., data may be written). In some cases, the transmission gates may be “closed (on)” when memory column 702 is in a “write” mode, where data may be written to memory cells 704 based on the differential input signal output by BL drivers 708a, 708b. As DCC repeater circuit 750 is connected via a shunt connection to the BLs of memory column 702, no break is made in the signal path, and repeater 712 does not need to be bypassed or disabled during memory read operations. Additionally, by connecting DCC repeater circuit 750 via a shunt connection, physical space for the memory array is optimized, differing from that of FIGS. 3 and 4. A shunt connection refers to a circuit whereby one or more components of the circuit (e.g., DCC repeater circuit 750) act as an alternative route for a signal to pass around another point. DCC repeater 712, for instance, is connected via a shunt connection as the differential signal can bypass DCC repeater circuit 750 (e.g., when in a “read” mode, as the signal can transmit from input nodes N_1a, N_1b to output nodes N_2a, N_2b without by conducted by the components of DCC repeater circuit 750).

In some embodiments, inverters 754a, 754b may be cross-coupled inverter pair. For instance, an output of first inverter 754a may be driven to be an input of second inverter 754b, and the output of second inverter 754b may be driven to be an input of first inverter 754a. This can enable the pair of inverters 754a, 754b to act as storage for repeater 712 (e.g., pair of inverters 754a, 754b may store a logical 0, 1), indicating an input signal value to be output to a subsequent memory cell (e.g., memory cell 704a may “after,” electrically, repeater 712. In some embodiments, each of inverters 754a, 754b may be formed from two transistors. Thus, a total number of transistors included in DCC repeater circuit 750 may be eight (8) transistors, which is half of the number of transistors employed by repeater 312a of FIG. 4 (e.g., which includes sixteen (16) transistors).

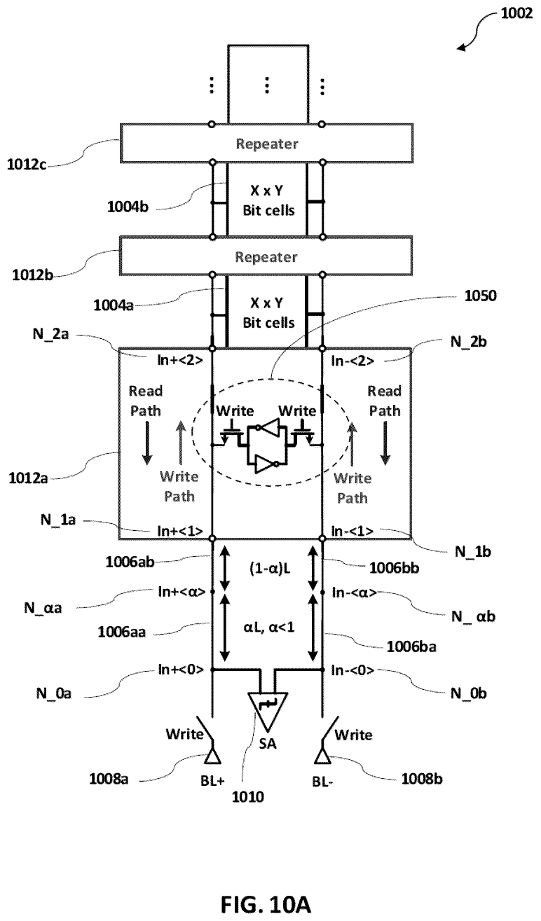

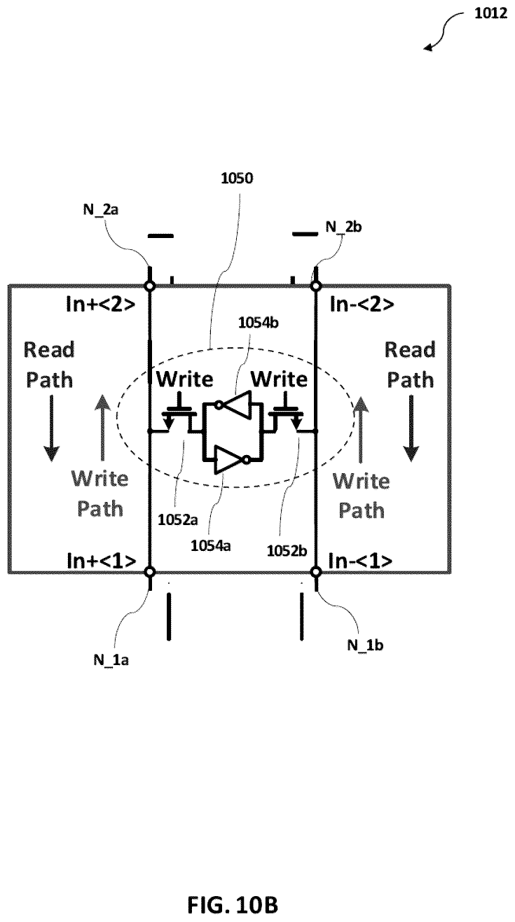

FIGS. 10A and 10B are an example memory column for a memory array including SRAM repeaters and zoom-in schematic of an example SRAM repeater, respectively, in accordance with various embodiments. FIG. 10A shows an example memory column 1002 of a memory array. In particular, a memory array may include n columns that are the same or similar to memory column 1002.

In some embodiments, memory column 1002 may include m memory cells, such as memory cells 1004a and 1004b, which may be connected in series to bit lines driven by bit line (BL) drivers 1008a, 1008b, respectively. Each memory cell of memory column 1002 may be include X×Y bit cells. Furthermore, each memory column may include a sense amplifier (SA) 1010, which may be used for reading data from the memory cells.

In some embodiments, initial nodes N_0a and N_0b may be coupled to BL drivers 1008a, 1008b, respectively. In some embodiments, an intermediate node, such as intermediate nodes N_αa, N_αb, may be inserted along the each bit line. In particular, intermediate nodes N_αa, N_αb may segment a length (L) of bit line between initial nodes N_0a, N_0b and intermediate nodes N_αa, N_αb into first portions 1006aa, 1006ba having a length αL, where a is less than 1, and second portions 1006ab, 1006bb, having a length (1−α) L. Nodes N_αa and N_αb may be placed at a balance point between the RC decay of the differential signal and DCC regeneration. For example, a may equal L/2. In some embodiments, a may be determined via simulation using constraints from the memory array's desired design. Memory column 1002 may function the same or similar to that of memory column 702, as the differential signal at the input of repeater 1012a is the same (or substantially similar) to the differential signal at the output of repeater 1012a. Furthermore, the effects of skew to the differential signal at each of the nodes in memory column 1002, as depicted by FIGS. 8A-8C and 9A-9C, may be substantially similar that that of memory column 702, described above, and the previous descriptions may apply.

FIG. 10B is an zoomed-in circuit diagram of an example repeater 1012 from memory column 1002. In particular, repeater 1012 may include input nodes N_1a, N_1b and output nodes N_2a, N_2b. SRAM repeater circuit 1050 may be inserted between the bit lines connecting input nodes N_1a, N_1b and output nodes N_2a, N_2b, respectively. For example SRAM repeater circuit 1050 may form a shunt connection to the bit lines. As a result, no signal path breaks may be included in memory column 1002 using SRAM repeater circuit 1050.

SRAM repeater circuit 1050 may include a first switch 1052a and a second switch 1052b. Each of switches 1052a, 1052b may switch “on” or “off,” depending on the input signal. For example, when provided with an input signal (e.g., a signal output by BL drivers 1008a, 1008b), the signal may be transmitted to inverters 1054a, 1054b. In some embodiments, switches 1052a, 1052b may be transmission gates formed using an NMOS transistor. For instance, when the input signal is logical high (e.g., logical 1), the device may be in a write mode (e.g., NMOS on, PMOS on), whereas when the input signal is logical low (e.g., logical 0), the device may be in read mode (e.g., NMOS off, PMOS off). When the signal across the transmission gates (e.g., switches 1052a, 1052b) is logical 1, the transmission gates may be “closed (on),” and the transistors of the transmission gates may conduct the input signal (e.g., data may be written). In some cases, the transmission gates may be “closed (on)” when memory column 1002 is in a “write” mode, where data may be written to memory cells 1004a, 100b based on the differential input signal output by BL drivers 1008a, 1008b. In some cases, the transmission gates may be “open (off)” when memory column 1002 is in a “read” mode, where data stored in each memory cell 704 may be readout across the bit lines and sensed by SA 710. When the signal across the transmission gates (e.g., switches 1052a, 1052b) is logical 1, the transmission gates may be “closed (on)” and the transistor of each transmission gate may conduct the input signal (e.g., data may be written). In some cases, the transmission gates may be “closed (on)” when memory column 1002 is in a “write” mode, where data may be written to memory cells 1004 based on the differential input signal output by BL drivers 1008a, 1008b. As SRAM repeater circuit 1050 is connected via a shunt connection to the BLs of memory column 1002, no break is made in the signal path, and repeater 1012 does not need to be bypassed or disabled during memory read operations. Additionally, by connecting SRAM repeater circuit 1050 via a shunt connection, physical space for the memory array is optimized, differing from that of FIGS. 3 and 4. SRAM repeater 1012, similar to that of DCC repeater 712a, is connected via a shunt connection as the differential signal can bypass SRAM repeater circuit 1050 (e.g., when in a “read” mode, as the signal can transmit from input nodes N_1a, N_1b to output nodes N_2a, N_2b without by conducted by the components of SRAM repeater circuit 1050).

In some embodiments, inverters 1054a, 1054b may be cross-coupled inverter pair. For instance, an output of first inverter 1054a may be driven to be an input of second inverter 1054b, and the output of second inverter 1054b may be driven to be an input of first inverter 1054a. This can enable the pair of inverters 1054a, 1054b to act as storage for repeater 1012 (e.g., pair of inverters 1054a, 1054b may store a logical 0, 1), indicating an input signal value to be output to a subsequent memory cell (e.g., memory cell 1004a may “after,” electrically, repeater 1012. In some embodiments, each of inverters 1054a, 1054b may be formed from two transistors. Thus, a total number of transistors included in SRAM repeater circuit 1050 may be six (6) transistors, which is less than half of the number of transistors employed by repeater 312a of FIG. 4 (e.g., which includes sixteen (16) transistors), and fewer transistors than DCC repeater circuit 750.

SRAM repeater 1012, including SRAM repeater circuit 1050, may provide additional improvements over the configuration of repeater 312a of FIGS. 3 and 4 beyond the use of fewer transistors (e.g., thereby decreasing cost). For example, the configuration of a memory array including memory columns, such as memory column 1002, including instances of SRAM repeater 1012 may reduce or eliminate the need for complimentary control signals, decreasing an amount of power needed by the memory array. For instance, a single-ended control signal may be the only signal needed. As another example, the SRAM-like configuration of repeater 1012 allows for simple incorporation into SRAM memory arrays. Repeater 1012 may have a layout pattern that is similar in configuration to that of an SRAM bit cell with a most compact layout, and may, similar to that of repeater 712a of FIG. 7A, be connected via a shunt connection, thereby eliminating the need to break the signal path for insertion. Thus, it can easily be merged into an SRAM memory array. The ability to merge SRAM repeaters, such as repeater 1012, into SRAM memory arrays can produce a height yield memory cell having identical surrounding SRAM-like repeater layouts (e.g., the memory array can include multiple bit-columns similar to that of bit-column 1002, each including multiple (X×Y) bit cells (e.g., memory cells 1004a-1004) and repeaters (e.g., repeaters 1012a-1012c).

Table 1 indicates the technical improvements and technical effects offered by each of the DCC repeater, as described above with respect to FIGS. 7A-7B, and the SRAM repeater, as described above by FIGS. 10A-10B.

TABLE 1

| Repeater Type | Buffer | DCC | SRAM |
|---|---|---|---|
| Configuration | Single-ended, | Differential | Differential |
| | Differential | | |
| Break In | Yes (Series | No (Shunt | No (Shunt |
| Signal Path? | Insertion) | Insertion) | Insertion) |
| Continuity? | No (Abrupt | Yes | Yes |
| | Discontinuity) | | |
| Propagation | Large | Small | Small |
| Delay | | | |
| Effective | Large | Small (αL), | Small (αL), |
| Driving Load | (Length L) | α < 1 | α < 1 |
| Read/Write | Separated | Identical | Identical |
| Paths? | | | |
| Skew | Yes | No (Reset) | No (Reset) |
| Propagation? | (Accumulated) | | |
| Number of | 16 transistors | 8 transistors | 6 transistors |
| Transistors | per bit | per bit | per bit |
| Used? | | | |
| Control Wires | 2 | 2 | 1 |
| | (Complementary) | (Complementary) | (Single-ended) |
| Capable of | No | No | No |
| being | | | |
| Merged into | | | |
| Memory? | | | |

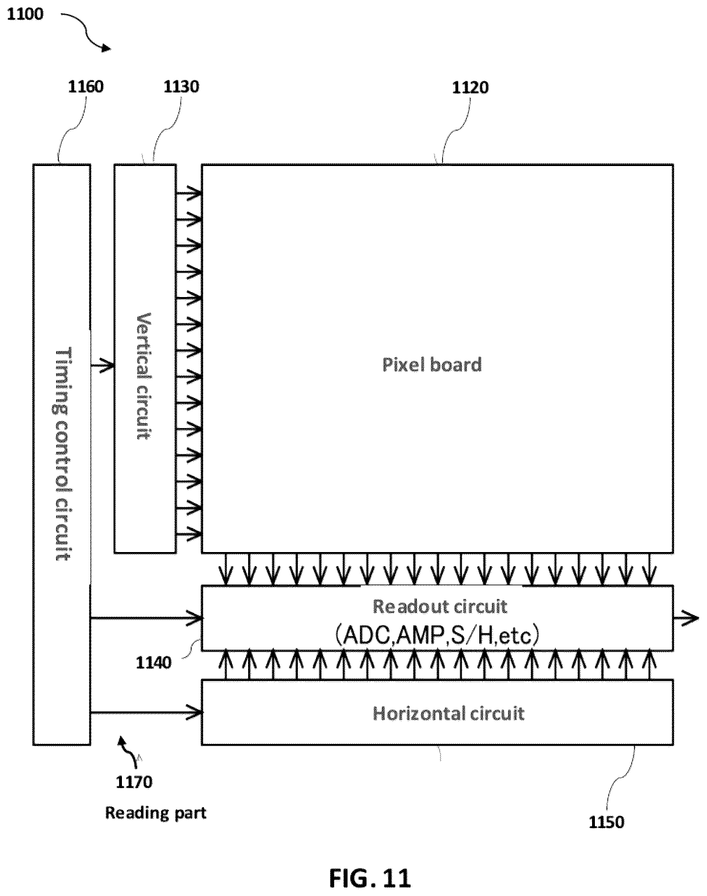

FIG. 11 is an example block diagram showing an example configuration of a solid-state imaging device, in accordance with various embodiments. In this embodiment, a solid-state imaging device 1100 is constituted by, for example, a CMOS image sensor. The CMOS image sensor is, for example, applied to a back-side illumination image sensor (BSI).

As shown in FIG. 11, solid-state imaging device 1100 may include a pixel part 1120 serving as an image capturing part, a vertical circuit 1130 (a row circuit), a reading circuit 1140 (a column reading circuit), a horizontal circuit 1150 (a column circuit), and a timing control circuit 1160. Among these components, for example, vertical circuit 1130, reading circuit 1140, horizontal circuit 1150, and timing control circuit 1160 may constitute reading part 1170 for reading out pixel signals. As an example, pixel part 1120 may include a memory array including one or more memory columns, such as memory columns 702 and 1002 of FIGS. 7A and 10A, respectively.

In some embodiments, pixels of solid-state imaging device 1100 may be arranged in a matrix pattern in pixel part 1120, and each multi-pixel may include at least two sub-pixels each having a photoelectric converting region. In some embodiments, the multi-pixel may include a back side separating part separating a plurality of adjacent sub-pixels from each other at least in a light entering portion of the photoelectric converting region of the multi-pixel and a single lens part allowing light to enter the photoelectric converting regions of at least two sub-pixels. In some embodiment, the optical center of the lens part may be positioned at the location where the back side separating part is formed, and at least the optical center region of the back side separating part exhibits lower reflection (higher absorption) than the other region of the back side separating part. In some embodiments, the optical center region of the back side separating part exhibits lower reflection (higher absorption) than the other region of the back side separating part.

In some embodiments, the multi-pixel serves as a unit group of sub-pixels and is configured as an NIR-RGB sensor.

The following briefly describes example configurations and functions of the parts of solid-state imaging device 1100.

Vertical circuit 1130 may drive the sub-pixels in shutter and read-out rows through the row-scanning control lines under the control of timing control circuit 1160. Furthermore, vertical circuit 1130 may output, according to address signals, row selection signals for row addresses of the read-out rows from which signals are to be read out and the shutter rows in which the charges accumulated in the photodiodes PD are reset.

In a normal pixel reading operation, vertical circuit 1130 of reading part 1170 may drive the pixels to perform shutter scanning and then reading scanning.

Reading circuit 1140 may include a plurality of column signal processing circuits arranged corresponding to the column outputs of pixel part 1120, and reading circuit 1140 may be configured such that the plurality of column signal processing circuits can perform column parallel processing. Reading circuit 1140 may include a correlated double sampling (CDS) circuit, an analog-to-digital converter (ADC), an amplifier (AMP), a sample/hold (S/H) circuit, and the like.

Reading circuit 1140 is applicable not only to a solid-state imaging device (CMOS image sensor) employing a rolling shutter as an electronic shutter but also to a solid-state imaging device (CMOS image sensor) employing a global shutter as an electronic shutter. For example, in a CMOS image sensor employing a global shutter as the electronic shutter, a pixel has therein a signal retaining part for retaining, in a sample-and-hold capacitor, a signal that is read out from a photoelectric conversion reading part, for example. The CMOS image sensor employing a global shutter stores the charges from the photodiodes in the sample-and-hold capacitors of the signal retaining parts at the same time in the form of voltage signals and subsequently sequentially read the voltage signals. In this way, the simultaneity is reliably achieved across the entire image. This CMOS image sensor is provided, for example, as a stacked CMOS image sensor.

The stacked CMOS image sensor may have a stacked structure in which a first substrate (a pixel die) and a second substrate (an ASIC die) are connected through microbumps (connecting parts), for example. The first substrate may have photoelectric conversion reading parts for individual pixels formed therein, and the second substrate may have signal retaining parts for the individual pixels, signal lines, a vertical circuit, a horizontal circuit, a reading circuit and the like formed therein. Each of the pixels formed in the first substrate may be connected to a corresponding one of the signal retaining parts formed in the second substrate, and the signal retaining parts may be connected to reading circuit 1140 including the above-described ADCs and S/H circuits.

Horizontal circuit 1150 may scan the signals processed in the plurality of column signal processing circuits of reading circuit 1140 such as ADCs, transfers the signals in a horizontal direction, and outputs the signals to a signal processing circuit (not shown).

Timing control circuit 1160 may generate timing signals required for signal processing in pixel part 1120, vertical circuit 1130, reading circuit 1140, horizontal circuit 1150, and the like.

In some embodiments, reading part 1170 can perform read-out scanning including: reading, in a reading period following a reset period PR in which the floating diffusion FD is reset, a signal in the reset state; and reading, in a reading period following a transfer period PT in which the charges stored in the first photodiode or the second photodiode may be transferred to the floating diffusion FD through the first transfer transistor or the second transfer transistor after the reading period following the reset period, a signal determined by the stored charges. Here, the first photodiode may have a first well capacity and a first responsivity and the second photodiode may have a second well capacity and a second responsivity. Reading part 1170 may be configured to perform at least one selected from the group consisting of first conversion gain mode reading and second conversion gain mode reading in a single reading period. In the first conversion gain mode reading, reading part 1170 can read pixel signals with a first conversion gain (for example, a high gain or HCG) corresponding to a first capacitance set by the capacitance changing part. In the second conversion gain mode reading, reading part 1170 can read pixel signals with a second conversion gain (for example, a low gain or LCG) corresponding to a second capacitance set by the capacitance changing part.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g. within a data center or geographically), or otherwise differently organized. The functionality described herein may be provided by one or more processors of one or more computers executing code stored on a tangible, non-transitory, machine readable medium. In some cases, notwithstanding use of the singular term “medium,” the instructions may be distributed on different storage devices associated with different computing devices, for instance, with each computing device having a different subset of the instructions, an implementation consistent with usage of the singular term “medium” herein.

The reader should appreciate that the present application describes several independently useful techniques. Rather than separating those techniques into multiple isolated patent applications, applicants have grouped these techniques into a single document because their related subject matter lends itself to economies in the application process. But the distinct advantages and aspects of such techniques should not be conflated. In some cases, embodiments address all of the deficiencies noted herein, but it should be understood that the techniques are independently useful, and some embodiments address only a subset of such problems or offer other, unmentioned benefits that will be apparent to those of skill in the art reviewing the present disclosure. Due to costs constraints, some techniques disclosed herein may not be presently claimed and may be claimed in later filings, such as continuation applications or by amending the present claims. Similarly, due to space constraints, neither the Abstract nor the Summary of the Invention sections of the present document should be taken as containing a comprehensive listing of all such techniques or all aspects of such techniques.

It should be understood that the description and the drawings are not intended to limit the present techniques to the particular form disclosed, but to the contrary, the intention is to cover all modifications, equivalents, and alternatives falling within the spirit and scope of the present techniques as defined by the appended claims. Further modifications and alternative embodiments of various aspects of the techniques will be apparent to those skilled in the art in view of this description. Accordingly, this description and the drawings are to be construed as illustrative only and are for the purpose of teaching those skilled in the art the general manner of carrying out the present techniques. It is to be understood that the forms of the present techniques shown and described herein are to be taken as examples of embodiments. Elements and materials may be substituted for those illustrated and described herein, parts and processes may be reversed or omitted, and certain features of the present techniques may be utilized independently, all as would be apparent to one skilled in the art after having the benefit of this description of the present techniques. Changes may be made in the elements described herein without departing from the spirit and scope of the present techniques as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an element” or “a element” includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. Limitations as to sequence of recited steps should not be read into the claims unless explicitly specified, e.g., with explicit language like “after performing X, performing Y,” in contrast to statements that might be improperly argued to imply sequence limitations, like “performing X on items, performing Y on the X'ed items,” used for purposes of making claims more readable rather than specifying sequence. Statements referring to “at least Z of A, B, and C,” and the like (e.g., “at least Z of A, B, or C”), refer to at least Z of the listed categories (A, B, and C) and do not require at least Z units in each category. Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device. Features described with reference to geometric constructs, like “parallel,” “perpendicular/orthogonal,” “square”, “cylindrical,” and the like, should be construed as encompassing items that substantially embody the properties of the geometric construct, e.g., reference to “parallel” surfaces encompasses substantially parallel surfaces. The permitted range of deviation from Platonic ideals of these geometric constructs is to be determined with reference to ranges in the specification, and where such ranges are not stated, with reference to industry norms in the field of use, and where such ranges are not defined, with reference to industry norms in the field of manufacturing of the designated feature, and where such ranges are not defined, features substantially embodying a geometric construct should be construed to include those features within 15% of the defining attributes of that geometric construct. The terms “first”, “second”, “third,” “given” and so on, if used in the claims, are used to distinguish or otherwise identify, and not to show a sequential or numerical limitation. As is the case in ordinary usage in the field, data structures and formats described with reference to uses salient to a human need not be presented in a human-intelligible format to constitute the described data structure or format, e.g., text need not be rendered or even encoded in Unicode or ASCII to constitute text; images, maps, and data-visualizations need not be displayed or decoded to constitute images, maps, and data-visualizations, respectively; speech, music, and other audio need not be emitted through a speaker or decoded to constitute speech, music, or other audio, respectively.

Those skilled in the art will recognize that the present teachings are amenable to a variety of modifications and/or enhancements. For example, although the implementation of various components described above may be embodied in a hardware device, it may also be implemented as a software only solution—e.g., an installation on an existing server. In addition, the conversation management techniques as disclosed herein may be implemented as a firmware, firmware/software combination, firmware/hardware combination, or a hardware/firmware/software combination.

While the foregoing has described what are considered to constitute the present teachings and/or other examples, it is understood that various modifications may be made thereto and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The present techniques will be better understood with reference to the following enumerated embodiments:
1. A repeater, comprising: a first input node coupled to a first bit line and a second input node coupled to a second bit line; a first output node coupled to the first bit line and a second output node coupled to the second bit line; a pair of switches configured to couple to the first bit line and the second bit line responsive to receiving an input signal; and a set of cross-coupled invertors coupled to the pair of switches, wherein the pair of switches and the set of cross-coupled invertors form a shunt connection between the first bit line and the second bit line responsive to the input signal being received by the pair of switches.
2. The repeater of embodiment 1, wherein one or more instances of the repeater is used within a memory array.
3. The repeater of any one of embodiments 1-2, wherein the first input node and the second input node are coupled to a memory cell.
4. The repeater of any one of embodiments 1-2, wherein the first output node and the second output node are coupled to a memory cell.
5. The repeater of embodiment 4, wherein the memory cell is an n-bit memory cell.
6. The repeater of embodiment 5, wherein the n-bit memory cell is a 1-bit memory cell.
7. The repeater of any one of embodiments 1-6, wherein the first input node and the second input node are coupled to a first intermediate node and a second intermediate node, respectively, which are coupled to a first initial node and a second initial node, respectively, which are respectively coupled to a first bit line driver and a second bit line driver.
8. The repeater of embodiment 7, wherein the first bit line driver and the second bit line driver are configured to output the input signal, the input signal being provided, via the first bit line and the second bit line, respectively, to the first initial node and the second initial node.
9. The repeater of embodiment 8, wherein the input signal is further provided to the pair of switches to cause the pair of switches to couple to the first bit line and the second bit line, respectively.
10. The repeater of any one of embodiments 7-9, wherein the first intermediate node and the second intermediate node are placed at a first location along a portion of the first bit line and the second bit line between the first initial node and the first input node, wherein the first location is a balance point.
11. The repeater of embodiment 10, wherein the balance point is determined via a simulation of the repeater's function.
12. The repeater of any one of embodiments 7-11, wherein: the input signal is a differential signal; at the first initial node and the second initial node, a leading edge of the differential signal takes a first amount of time to go from a first logical level to a second logical level; at the first intermediate node and the second intermediate node, the leading edge of the differential signal takes a second amount of time to go from the first logical level to the second logical level, wherein the second amount of time is greater than the first amount of time; at the first input node and the second input node, the leading edge of the differential signal takes a third amount of time to go from the first logical level to the second logical level, wherein the third amount of time is larger or less than the second amount of time.
13. The repeater of embodiment 12, wherein: at the first initial node and the second initial node, each component of the differential signal intersects at a mid-point between the first logical level and the second logical level; at the first intermediate node and the second intermediate node, each component of the differential signal intersects at a first zero crossing point, the first zero crossing point being skewed to towards the first logical level or the second logical level; at the first input node and the second input node, each component of the differential signal intersects at the mid-point between the first logical level and the second logical level; and at the first output node and the second output node, each component of the differential signal is equal to a respective component at the first input node and the second input node, respectively.
14. The repeater of any one of embodiments 1-13, wherein: each switch of the pair of switches comprise a PMOS transistor and an NMOS transistor; the repeater includes eight transistors; and the repeater is a Duty-Cycle Corrector (DCC) repeater.
15. The repeater of any one of embodiments 1-14, wherein: each switch of the pair of switches comprise an NMOS transistor; the repeater includes six transistors; and the repeater is an SRAM repeater.
16. The repeater of any one of embodiments 1-15, wherein the first output node and the second output node are coupled to a memory cell, and the memory cell is coupled to an additional instance of the repeater.
17. The repeater of any one of embodiments 1-16, further comprising: means for reading data.
18. The repeater of any one of embodiments 1-17, further comprising: means for writing data.
19. The repeater of any one of embodiments 1-18, further comprising: means for generating the input signal.
20. A cascading stack for a memory array, comprising: a plurality of memory cells; and a plurality of repeaters, each coupled to a respective one of the plurality of memory cells, wherein each repeater comprises the repeater of any one of embodiments 1-19.
21. A memory array, comprising: a plurality of repeaters, each repeater of the plurality of repeaters comprising the repeater of any one of embodiments 1-19.
22. A memory array, comprising: a plurality of memory cells configured to store data; a pair of bit line (BL) drivers configured to provide a input signal for writing data to at least some of the plurality of memory cells; a sense amplifier communicatively coupled to the bit line drivers to read data stored by at least some of the memory cells; and a plurality of repeaters connected to the plurality of memory cells, wherein each repeater of the plurality of repeaters comprises the repeater of any one of embodiments 1-19.
23. An imaging device comprising: a plurality of repeaters coupled to memory cells, wherein each repeater of the plurality of repeaters comprises the repeater of any one of embodiments 1-19.

What is claimed is:

1. A memory array, comprising:
a plurality of memory cells configured to store data;
a pair of bit line drivers configured to provide a differential signal for writing data to at least some of the plurality of memory cells along a pair of bit lines;
a sense amplifier communicatively coupled to the bit line drivers to read data stored by at least some of the plurality of memory cells; and
a plurality of repeaters connected in series to the plurality of memory cells, each repeater of the plurality of repeaters being connected, via a respective shunt connection, to the pair of BL drivers, wherein each repeater of the plurality of repeaters comprises:
an input node and an output node along each bit line;
a set of cross-coupled inverters configured to receive, regenerate, and output the differential signal;
a first switch and a second switch configured to provide the differential signal to the set of cross-coupled inverters when in write mode or bypass the set of cross-coupled inverters when in read mode, and wherein:
the pair of bit lines connect to the pair of BL drivers at a first node,
an intermediate node is placed along each bit line between the first node and the input node of a first repeater of the plurality of repeaters, and
an additional intermediate node is placed along each bit line between the output node of a given repeater and the input node of a subsequent repeater.

2. The memory array of claim 1, wherein the intermediate node and each additional intermediate node are placed at a balance point of a respective bit line.

3. The memory array of claim 1, wherein each repeater of the plurality of repeaters is:
a duty-cycle corrector (DCC) repeater comprising eight (8) transistors; or
an SRAM repeater comprising six (6) transistors.

4. The memory array of claim 3, wherein:
the DCC repeater includes the set of cross-coupled inverters and a pair of transmission gates each including a PMOS transistor and an NMOS transistor; and
the SRAM repeater includes the set of cross-coupled inverters and a pair of transmission gates including an NMOS transistor.

5. A repeater for a memory array, comprising:
a first input node coupled to a first bit line and a second input node coupled to a second bit line;
a first output node coupled to the first bit line and a second output node coupled to the second bit line;
a pair of switches configured to couple to the first bit line and the second bit line responsive to receiving an input signal; and
a set of cross-coupled invertors coupled to the pair of switches, wherein the pair of switches and the set of cross-coupled invertors form a shunt connection between the first bit line and the second bit line responsive to the input signal being received by the pair of switches.

6. The repeater of claim 5, wherein the first input node and the second input node are coupled to a first intermediate node and a second intermediate node, respectively, which are coupled to a first initial node and a second initial node, respectively, which are respectively coupled to a first bit line driver and a second bit line driver.

7. The repeater of claim 6, wherein the first bit line driver and the second bit line driver are configured to output the input signal, the input signal being provided, via the first bit line and the second bit line, respectively, to the first initial node and the second initial node, and the input signal also being provided to the pair of switches to cause the pair of switches couple to the first bit line and the second bit line, respectively.

8. The repeater of claim 6, wherein the first intermediate node and the second intermediate node are placed at a first location along a portion of the first bit line and the second bit line between the first initial node and the first input node, wherein the first location is a balance point.

9. The repeater of claim 6, wherein:
the input signal is a differential signal;
at the first initial node and the second initial node, a leading edge of the differential signal takes a first amount of time to from go from a first logical level to a second logical level;
at the first intermediate node and the second intermediate node, the leading edge of the differential signal takes a second amount of time to go from the first logical level to the second logical level, wherein the second amount of time is greater than the first amount of time;
at the first input node and the second input node, the leading edge of the differential signal takes a third amount of time to go from the first logical level to the second logical level, wherein the third amount of time is less than or larger than the second amount of time.

10. The repeater of claim 9, wherein:
at the first initial node and the second initial node, each component of the differential signal intersects at a mid-point between the first logical level and the second logical level;
at the first intermediate node and the second intermediate node, each component of the differential signal intersects at a zero crossing point, the zero crossing point being skewed to towards the first logical level or the second logical level;
at the first input node and the second input node, each component of the differential signal intersects at the mid-point between the first logical level and the second logical level; and
at the first output node and the second output node, each component of the differential signal is equal to a respective component at the first input node and the second input node, respectively.

11. The repeater of claim 5, wherein:
each switch of the pair of switches comprise a PMOS transistor and an NMOS transistor;
the repeater includes eight transistors; and
the repeater is a Duty-Cycle Corrector (DCC) repeater.

12. The repeater of claim 5, wherein:
each switch of the pair of switches comprise an NMOS transistor;
the repeater includes six transistors; and
the repeater is an SRAM repeater.

13. The repeater of claim 5, wherein the first output node and the second output node are coupled to a memory cell, and the memory cell is coupled to an additional instance of the repeater.

14. The repeater of claim 5, further comprising:
means for reading data stored in a memory cell; and
means for writing data to a memory cell.

15. A cascading stack for a memory array, comprising:
a plurality of memory cells; and
a plurality of repeaters, each coupled to a respective one of the plurality of memory cells, wherein each repeater comprises:
a first input node coupled to a first bit line and a second input node coupled to a second bit line;
a first output node coupled to the first bit line and a second output node coupled to the second bit line;
a pair of switches configured to couple to the first bit line and the second bit line responsive to receiving an input signal; and
a set of cross-coupled invertors coupled to the pair of switches, wherein the pair of switches and the set of cross-coupled invertors form a shunt connection between the first bit line and the second bit line responsive to the input signal being received by the pair of switches.
